(19) United States
(12) Patent Application Publication
(10) Pub. No.: US 2012/0102374 A1
(43) Pub. Date: Apr. 26, 2012

(54) STORAGE DEVICE TESTING

(75) Inventors: Edward Garcia, Holbrook, MA (US); Brian S. Merrow, Harvard, MA (US); Evgeny Polyakov, Brookline, MA (US); Walter Vahey, Winchester, MA (US); Eric L. Truebenbach, Sudbury, MA (US)

(73) Assignee: TERADYNE, INC., North Reading, MA (US)

(21) Appl. No.: 13/264,665

(22) PCT Filed: Apr. 17, 2009
(86) PCT No.: PCT/US2009/040895

§ 371 Date: Jan. 6, 2012

(51) Int. Cl. G11C 29/08; G06F 11/26; B25J 13/08; B65H 1/00; G06F 7/00

(52) U.S. Cl. 714/718; 414/222.07; 700/218; 700/254; 901/47; 901/9; 714/E11.159

(57) ABSTRACT

A storage device testing system (100) includes at least one 310 robotic arm (200) defining a first axis (205) substantially normal to a 300 floor surface (10). The robotic arm is operable to rotate through a predetermined arc about and extend radially from the first axis. Multiple racks (300) are arranged around the robotic arm for servicing by the robotic arm. Each rack houses multiple test slots (310) that are each configured to receive a storage device transporter (550) configured to carry a storage device (500) for testing.

### TECHNICAL FIELD

This disclosure relates to storage device testing.

### BACKGROUND

Disk drive manufacturers typically test manufactured disk drives for compliance with a collection of requirements. Test equipment and techniques exist for testing large numbers of disk drives serially or in parallel. Manufacturers tend to test large numbers of disk drives simultaneously in batches. Disk drive testing systems typically include one or more racks having multiple test slots that receive disk drives for testing.

The testing environment immediately around the disk drive is closely regulated. Minimum temperature fluctuations in the testing environment are critical for accurate test conditions and for safety of the disk drives. The latest generations of disk drives, which have higher capacities, faster rotational speeds and smaller head clearance, are more sensitive to vibration. Excess vibration can affect the reliability of test results and the integrity of electrical connections. Under test conditions, the drives themselves can propagate vibrations through supporting structures or fixtures to adjacent units. This vibration “cross-talking,” together with external sources of vibration, contributes to bump errors, head slap and non-repetitive run-out (NRRO), which may result in lower test yields and increased manufacturing costs.

Current disk drive testing systems employ automation and structural support systems that contribute to excess vibrations in the system and/or require large footprints. Current disk drive testing systems also use an operator or conveyer belt to individually feed disk drives to the testing system for testing.

### SUMMARY

In one aspect, a storage device testing system includes at least one robotic arm defining a first axis substantially normal to a floor surface. The robotic arm is operable to rotate through a predetermined arc (e.g. 360°) about, and to extend radially from, the first axis. Multiple racks are arranged around the robotic arm for servicing by the robotic arm. Each rack houses multiple test slots that are each configured to receive a storage device transporter configured to carry a storage device for testing.

Implementations of the disclosure may include one or more of the following features. In some implementations, the robotic arm includes a manipulator configured to engage the storage device transporter of one of the test slots. The robotic arm is operable to carrying a storage device in the storage device transporter to the test slot for testing. The robotic arm defines a substantially cylindrical working envelope volume, and the racks and the transfer station are arranged within the working envelope volume for servicing by the robotic arm. In some examples, the racks and the transfer station are arranged in at least a partially closed polygon about the first axis of the robotic arm. The racks may be arranged equidistantly radially away from the first axis of the robotic arm or at different distances.

The robotic arm may independently services each test slot by retrieving the storage device transporter from one of the test slots to transfer a storage device between a transfer station and the test slot. In some implementations, the storage device testing system includes a vertically actuating support that supports the robotic arm and is operable to move the robotic arm vertically with respect to the floor surface. The storage device testing system may also include a linear actuator that supports the robotic arm and is operable to move the robotic arm horizontally along the floor surface. In some implementations, the storage device testing system includes a rotatable table that supports the robotic arm and is operable to rotate the robotic arm about a second axis substantially normal to the floor surface.

The storage device testing system may include a transfer station arranged for servicing by the robotic arm. The transfer station is configured to supply and/or store storage devices for testing. In some implementations, the transfer station is operable to rotate about a longitudinal axis defined by the transfer station substantially normal to a floor surface. The transfer station includes a transfer station housing that defines first and second opposite facing tote receptacles. In some examples, the transfer station includes a station base, a spindle extending upwardly substantially normal from the station base, and multiple tote receivers rotatably mounted on the spindle. Each tote receiver is independently rotatable of the other and defines first and second opposite facing tote receptacles.

The robotic arm may independently service each test slot by transferring a storage device between a received storage device tote of the transfer station and the test slot. In some implementations, the storage device tote includes a tote body defining multiple storage device receptacles configured to each house a storage device. Each storage device receptacle defines a storage device support configured to support a central portion of a received storage device to allow manipulation of the storage device along non-central portions. In some examples, the storage device tote includes a tote body defining multiple column cavities and multiple cantilevered storage device supports disposed in each column cavity (e.g. off a rear wall of the cavity column), dividing the column cavity into multiple storage device receptacles that are each configured to receive a storage device. Each storage device support is configured to support a central portion of a received storage device to allow manipulation of the storage device along non-central portions.

The storage device testing system sometimes includes a vision system disposed on the robotic arm to aiding guidance of the robotic arm while transporting a storage device. In particular, the vision system may used to guide a manipulator on the robotic arm that holds the storage device transporter to insert the storage device transporter safely into one of the test slots or a storage device tote. The vision system may calibrate the robotic arm by aligning the robotic arm to a fiducial mark on the rack, test slot, transfer station, and/or storage device tote.

In some implementations, the storage device testing system includes at least one computer in communication with the test slots. A power system supplies power to the storage device testing system and may be configured to monitor and/or regulate power to the received storage device in the test slot. A temperature control system controls the temperature of each test slot. The temperature control system may include an air mover (e.g. fan) operable to circulate air over and/or through the test slot. A vibration control system controls rack vibrations (e.g. via passive dampening). A data interface is in communication with each test slot and is configured to communicate with a storage device in the storage device transporter received by the test slot.

Each rack may include at least one self-testing system in communication with at least one test slot. The self-testing system includes a cluster controller, a connection interface circuit in electrical communication with a storage device received in the test slot, and a block interface circuit in electrical communication with the connection interface circuit. The block interface circuit is configured to control power and temperature of the test slot. The connection interface circuit and the block interface circuit are configured to test the functionality of at least one component of the storage device testing system (e.g. test the functionality of the test slot while empty or while housing a storage device held by a storage device transporter).

In some implementations, each rack includes at least one functional testing system in communication with at least one test slot. The functional testing system includes a cluster controller, at least one functional interface circuit in electrical communication with the cluster controller, and a connection interface circuit in electrical communication with a storage device received in the test slot and the functional interface circuit. The functional interface circuit is configured to communicate a functional test routine to the storage device. In some examples, the functional testing system includes an Ethernet switch for providing electrical communication between the cluster controller and the at least one functional interface circuit.

In another aspect, a method of performing storage device testing includes presenting a storage device for testing, actuating a single robotic arm to retrieve the presented storage device and carry the storage device to a test slot housed in a rack of a storage device testing system. The robotic arm is operable to rotate through a predetermined arc about and to extend radially from a first axis defined by the robotic arm substantially normal to a floor surface. The method includes actuating the robotic arm to insert the storage device into the test slot, performing a functionality test on the storage device housed in the test slot, and actuating the robotic arm to retrieve the tested storage device from the test slot and deliver the tested storage device to a tested complete location, such as a transfer station. In some implementations, the method further includes loading the storage device into a transfer station, such that the storage device is presented for testing, actuating the robotic arm to retrieve a storage device transporter from the test slot, actuating the robotic arm to retrieve the presented storage device from the transfer station and carry the storage device in the storage device transporter. The method includes actuating the robotic arm to deliver the storage device transporter carrying storage device to the test slot, and, for examples after testing, actuating the robotic arm to retrieve the storage device transporter carrying the tested storage device from the test slot and deliver the tested storage device back to the transfer station.

In yet another aspect, a method of performing storage device testing includes loading multiple storage devices into a transfer station (e.g. as by loading the storage devices into storage device receptacles defined by a storage device tote, and loading the storage device tote into a tote receptacle defined by a transfer station). The method includes actuating a robotic arm to retrieve a storage device transporter from a test slot housed in a rack, and actuating the robotic arm to retrieve one of the storage devices from the transfer station and carry the storage device in the storage device transporter. The robotic arm is operable to rotate through a predetermined arc about, and to extend radially from, a first axis defined by the robotic arm substantially normal to a floor surface. The method includes actuating the robotic arm to deliver the storage device transporter carrying a storage device to the test slot, and performing a functionality test on the storage device housed by the received storage device transporter and the test slot. The method then includes actuating the robotic arm to retrieve the storage device transporter carrying the tested storage device from the test slot and deliver the tested storage device back to the transfer station.

In some examples, the method includes actuating the robotic arm to deposit the storage device transporter in the test slot (e.g. after depositing the tested storage device in a storage device receptacle of the storage device tote). In some examples, delivering the storage device transporter to the test slot includes inserting the storage device transporter carrying the storage device into the test slot in the rack, establishing an electric connection between the storage device and the rack.

In some implementations, performing a functionality test on the received storage device includes regulating the temperature of the test slot while operating the storage device. Also, operating the received storage device may include performing reading and writing of data to the storage device. In some examples, the method includes one or more of circulating air over and/or through the test slot to control the temperature of the test slot, monitoring and/or regulating power delivered to the received storage device, and performing a self-test on the test slot with a self-testing system housed by the rack to verify the functionality of the test slot.

The method may include communicating with a vision system disposed on the robotic arm to aid guidance of the robotic arm while transporting the storage device. The method may also include calibrating the robotic arm by aligning the robotic arm to a fiducial mark on the rack, test slot, transfer station, and/or storage device tote recognized by the vision system.

The details of one or more implementations of the disclosure are set forth in the accompanying drawings and the description below. Other features, objects, and advantages will be apparent from the description and drawings, and from the claims.

### DESCRIPTION OF DRAWINGS

FIG. 1 is a perspective view of a storage device testing system.

FIG. 2 is a top view of a storage device testing system.

FIG. 3 is a perspective view of a storage device testing system.

FIGS. 4-5 are top views storage device testing systems having different sized racks and footprints.

FIG. 6 is a perspective view of a storage device testing system.

FIG. 7 is a side view of a robotic am supported on vertical and horizontal actuating supports.

FIG. 8 is a perspective view of a storage device testing system having two robotic arms.

FIG. 9 is a top view of a storage device testing system including a robotic arm supported on a rotating support.

FIG. 10 is a perspective view of a transfer station.

FIG. 11 is a perspective view of a tote defining multiple storage device receptacles.

FIG. 12 is a perspective view of a tote having cantilevered storage device supports.

FIG. 13 is a perspective view of a storage device transporter.

FIG. 14 is a perspective view of a storage device transporter carrying a storage device.

FIG. 15 is a bottom perspective view of a storage device transporter carrying a storage device.

FIG. 16 is a perspective view of a storage device transporter carrying a storage device aligned for insertion into a test slot.

FIG. 17 is a schematic view of a storage device testing system.

FIG. 18 is a schematic view of a storage device testing system with self-testing and functional testing capabilities.

Like reference symbols in the various drawings indicate like elements.

### DETAILED DESCRIPTION

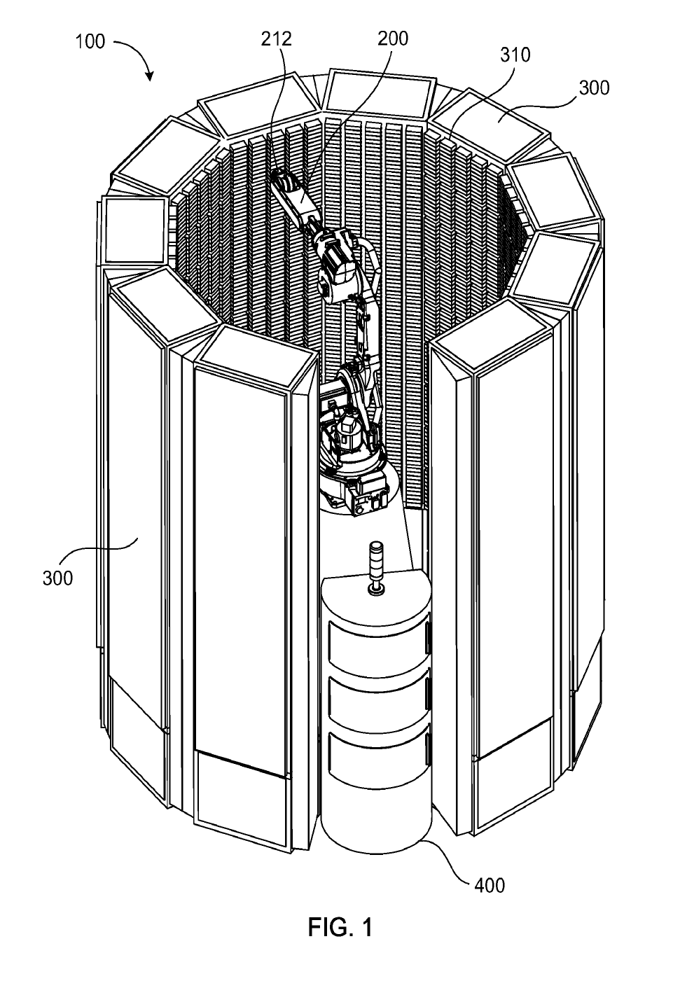

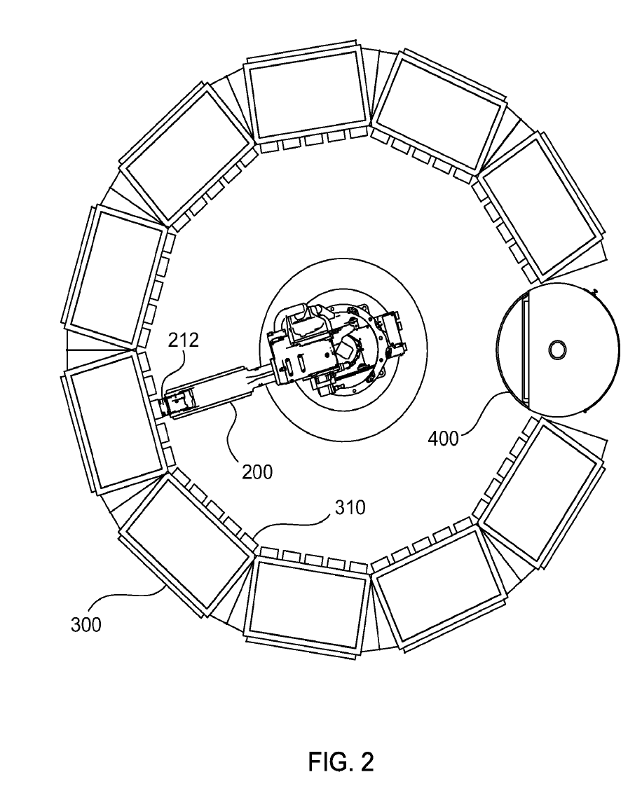

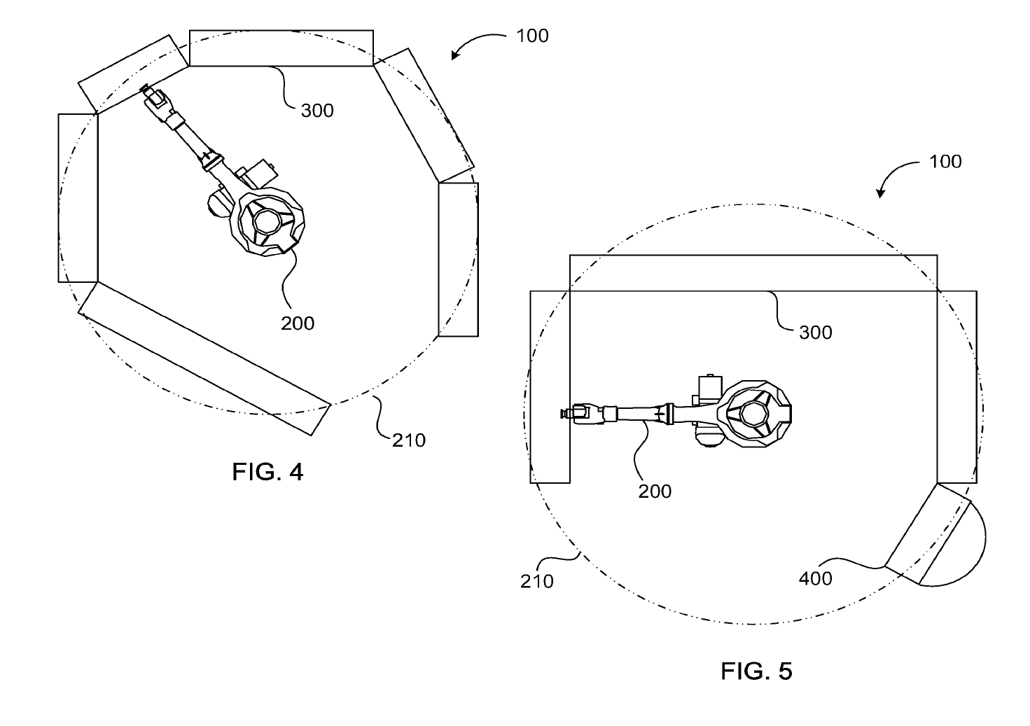

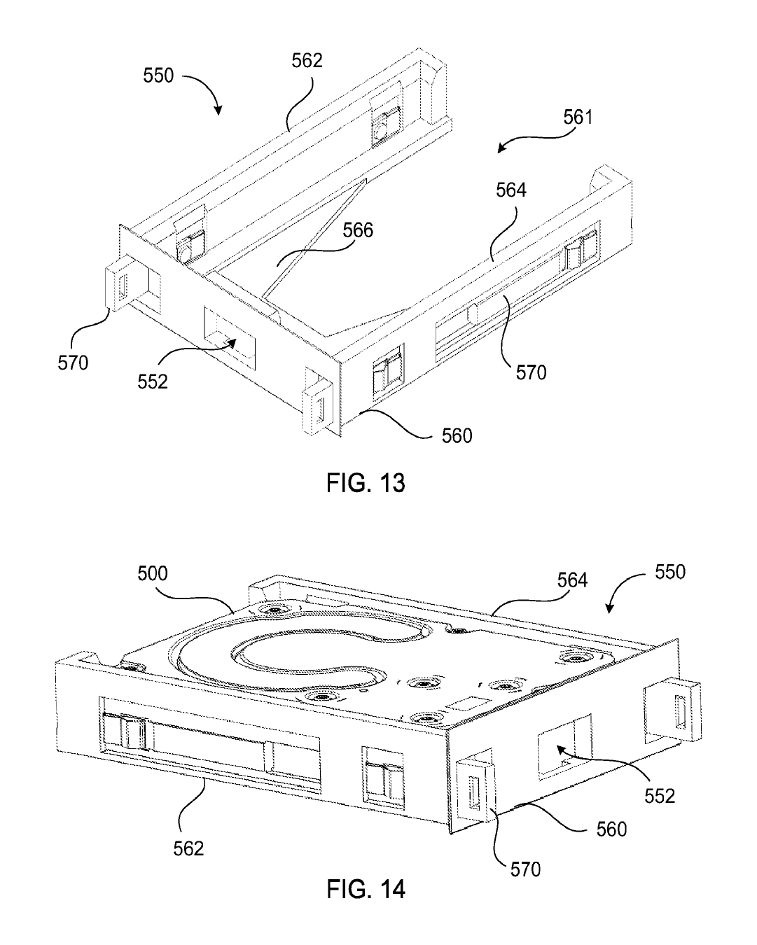

Referring to FIGS. 1-3, in some implementations, a storage device testing system 100 includes at least one robotic arm 200 defining a first axis 205 substantially normal to a floor surface 10. The robotic arm 200 is operable to rotate through a predetermined arc about the first axis 205 and to extend radially from the first axis 205. In some examples, the robotic arm 200 is operable to rotate 360° about the first axis 205 and includes a manipulator 212 disposed at a distal end of the robotic arm 200 to handle a storage device 500 and/or a storage device transporter 550 carrying the storage device 500 (see e.g. FIGS. 13-14). Multiple racks 300 are arranged around the robotic arm 200 for servicing by the robotic arm 200. Each rack 300 houses multiple test slots 310 configured to receive storage devices 500 for testing. The robotic arm 200 defines a substantially cylindrical working envelope volume 210, with the racks 300 being arranged within the working envelope volume 210 (see e.g. FIGS. 4 and 5) for accessibility of each test slot 310 for servicing by the robotic arm 200. The substantially cylindrical working envelope volume 210 provides a compact footprint and is generally only limited in capacity by height constraints.

A storage device, as used herein, includes disk drives, solid state drives, memory devices, and any device that requires asynchronous testing for validation. A disk drive is generally a non-volatile storage device which stores digitally encoded data on rapidly rotating platters with magnetic surfaces. A solid-state drive (SSD) is a data storage device that uses solid-state memory to store persistent data. An SSD using SRAM or DRAM (instead of flash memory) is often called a RAM-drive. The term solid-state generally distinguishes solid-state electronics from electromechanical devices.

The robotic arm 200 may be configured to independently service each test slot 310 to provide a continuous flow of storage devices 500 through the testing system 100. A continuous flow of individual storage devices 500 through the testing system 100 allows random start and stop times for each storage device 500, whereas systems that require batches of storage devices 500 to be run at once must all have the same start and end times. Therefore, with continuous flow, storage devices 500 of different capacities can be run at the same time and serviced (loaded/unloaded) as needed.

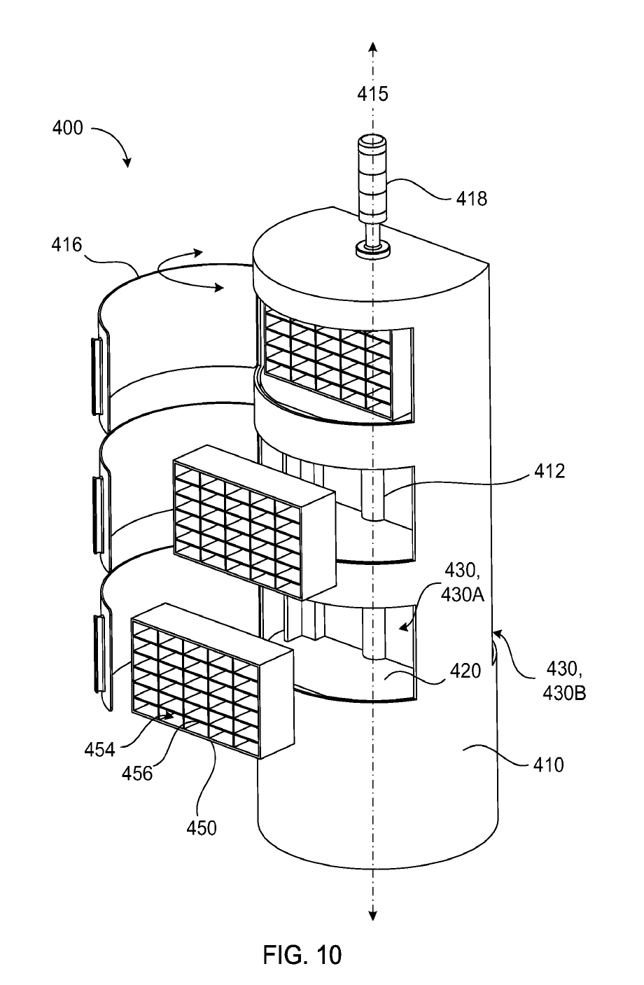

Isolation of the free standing robotic arm 200 from the racks 300 aids vibration control of the racks 300, which only shares the floor surface 10 (see e.g. FIG. 10) as a common support structure. In other words, the robotic arm 200 is decoupled from the racks 300 and only shares the floor surface 10 as the only means of connection between the two structures. In some instances, each rack 300 houses about 480 test slots 310. In other instances, the racks 300 vary in size and test slot capacity.

In the examples illustrated in FIGS. 1-3, the racks 300 are arranged equidistantly radially away from the first axis 205 of the robotic arm 200. However, the racks 300 may be arranged in any pattern and at any distance around the robotic arm 200 within the working envelope volume 210. The racks 300 are arranged in at least a partially closed polygon about the first axis 205 of the robotic arm 200, such as an open or closed octagon, square, triangle, trapezoid, or other polygon, examples of which are shown in FIGS. 4-5. The racks 300 may be configured in different sizes and shapes to fit a particular footprint. The arrangement of racks 300 around the robotic arm 200 may be symmetric or asymmetric.

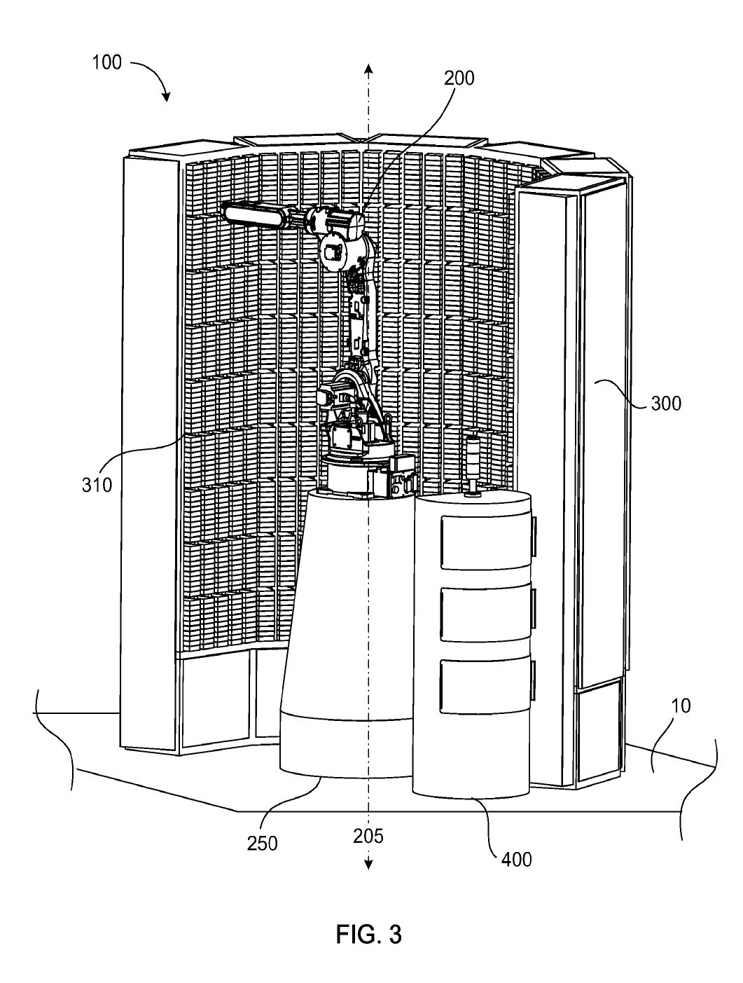

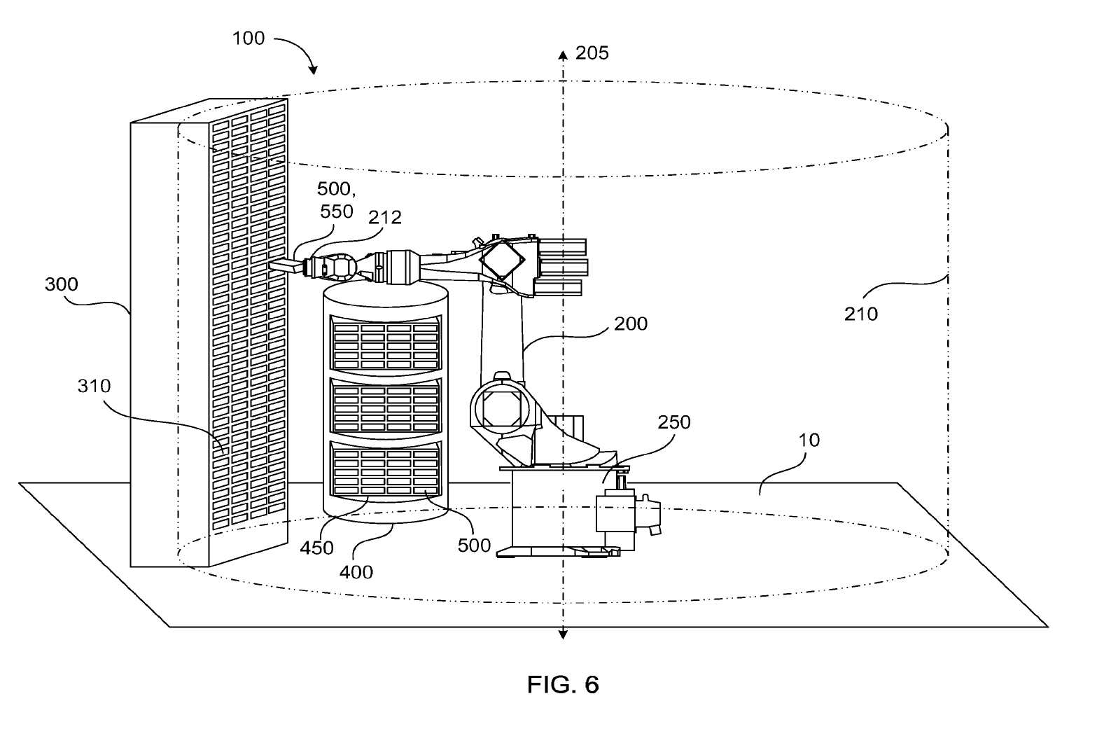

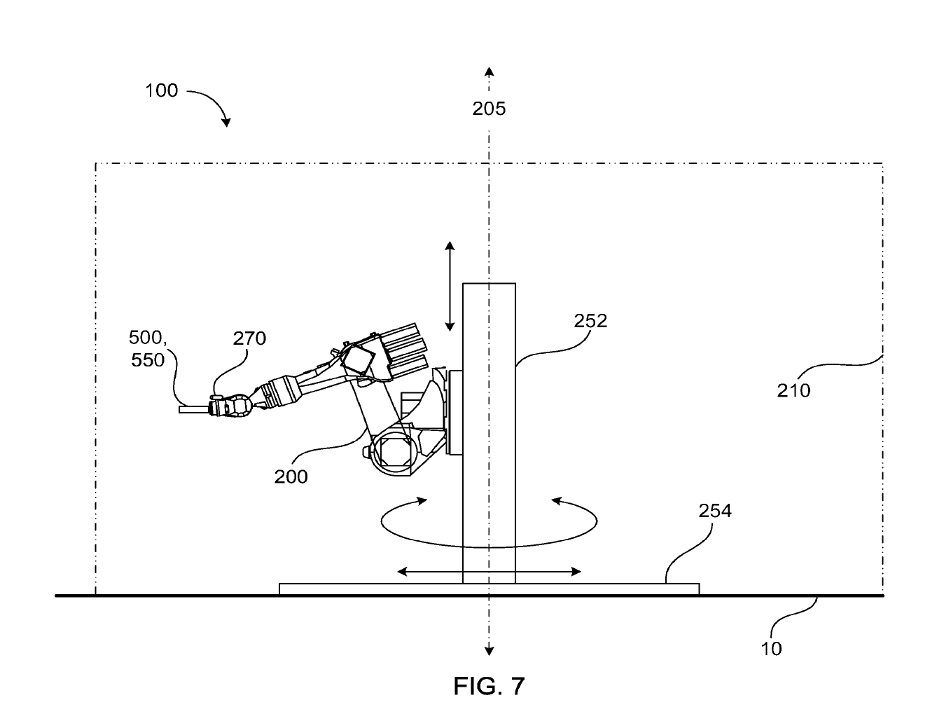

In the example shown in FIGS. 3 and 6, the robotic arm 200 is elevated by and supported on a pedestal or lift 250 on the floor surface 10. The pedestal or lift 250 increases the height of the working envelope volume 210 by allowing the robotic arm 200 to reach not only upwardly, but also downwardly to service test slots 310. The height of the working envelope volume 210 can be further increased by adding a vertical actuator to the pedestal or lift 250, configuring it as a vertically actuating support 252 that supports the robotic arm 200, as shown in FIG. 7. The vertically actuating support 252 is operable to move the robotic arm 200 vertically with respect to the floor surface 10. In some examples, the vertically actuating support 252 is configured as a vertical track supporting the robotic arm 200 and includes an actuator (e.g. driven ball-screw or belt) to move the robotic arm 200 vertically along the track. A horizontally actuating support 254 (e.g. a linear actuator), also shown in FIG. 7, may be used to support the robotic arm 200 and be operable to move the robotic arm 200 horizontally along the floor surface 10. In the example shown, the combination of the vertically and horizontally actuating supports 252, 254 supporting the robotic arm 210 provides an enlarged working envelope volume 210 having an elongated substantially elliptical profile from a top view.

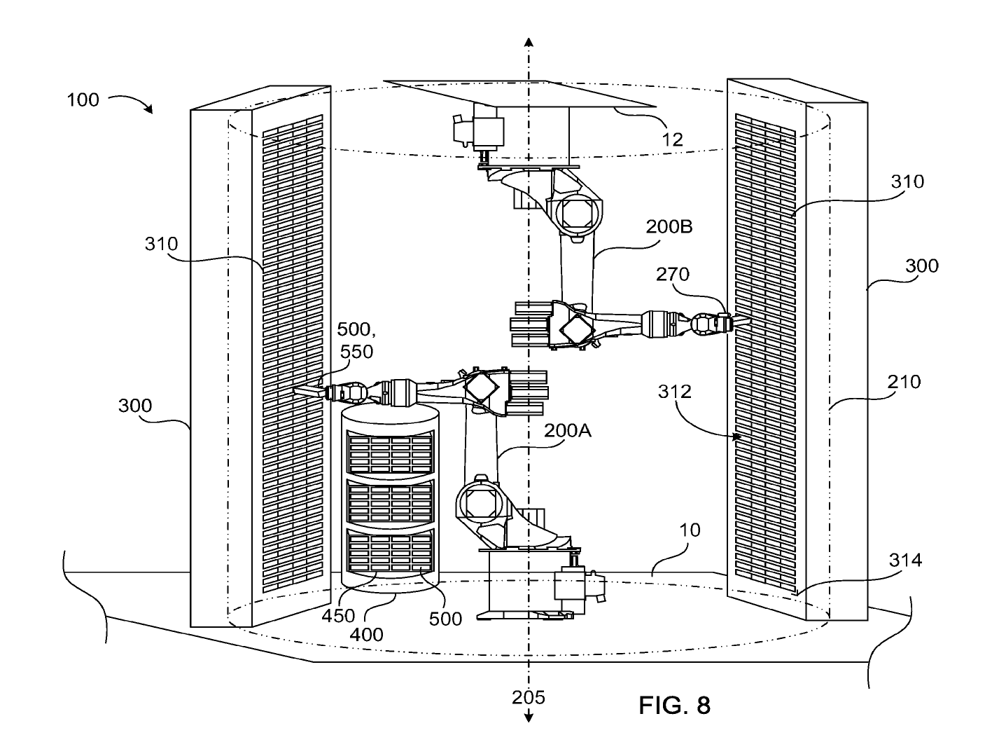

In the example illustrated in FIG. 8, the storage device testing system 100 includes two robotic arms 200A and 200B, both rotating about the first axis 205. One robotic arm 200A is supported on the floor surface 10, while the other robotic arm 200B is suspended from a ceiling structure 12. Similarly, in the example shown in FIG. 7, additional robotic arms 200 may be operational on the vertically actuating support 252.

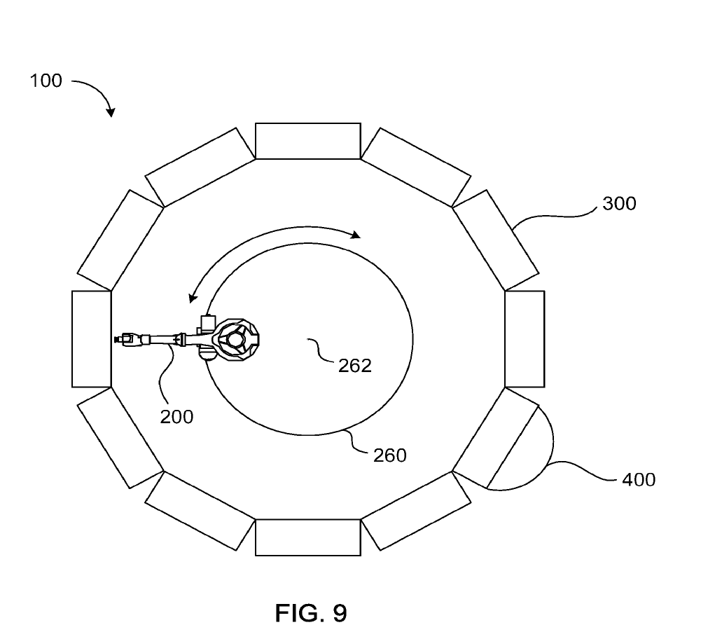

In the example illustrated in FIG. 9, the storage device testing system 100 includes a rotatable table 260 that supports the robotic arm 200. The rotatable table 260 is operable to rotate the robotic arm 200 about a second axis 262 substantially normal to the floor surface 10, thereby providing a larger working envelope volume 210 than a robotic arm 200 rotating only about the first axis 205.

Referring back to FIGS. 7-8, in some implementations, the storage device testing system 100 includes a vision system 270 disposed on the robotic arm 200. The vision system 270 is configured to aid guidance of the robotic arm 200 while transporting a storage device 500. In particular, the vision system 270 aids alignment of the storage device transporter 550, held by the manipulator 212, for insertion in the test slot 310 and/or tote 450. The vision system 270 calibrates the robotic arm 200 by aligning the robotic arm 200 to a fiducial mark 314 on the rack 300, preferably the test slot 310. In some examples, the fiducial mark 314 is an “L” shaped mark located near a corner of an opening 312 of the test slot 310 on the rack 300. The robotic arm 200 aligns itself with the fiducial mark 314 before accessing the test slot 310 (e.g. to either pick-up or place a storage device transporter 550, which may be carrying a storage device 500). The continual robotic arm alignments enhances the accuracy and reputability of the robotic arm 200, while minimizing misplacement of a storage device transporter 550 carrying a storage device 500 (which may result in damage to the storage device 500 and/or the storage device testing system 100).

In some implementations, the storage device testing system 100 includes a transfer station 400, as shown in FIGS. 1-3 and 10. While in other implementations, the storage device testing system 100 include may include a conveyor belt (not shown) or an operator that feeds storage devices 500 to the robotic arm 200. In examples including a transfer station 400, the robotic arm 200 independently services each test slot 310 by transferring a storage device 500 between the transfer station 400 and the test slot 310. The transfer station 400 includes multiple tote receptacles 430 configured to each receive a tote 450. The tote 450 defines storage device receptacles 454 that house storage devices 500 for testing and/or storage. In each storage device receptacle 454, the housed storage device 500 is supported by a storage device support 456. The robotic arm 200 is configured to remove a storage device transporter 550 from one of the test slots 310 with the manipulator 212, then pick up a storage device 500 from one the storage device receptacles 454 at the transfer station 400 with the storage device transporter 550, and then return the storage device transporter 550, with a storage device 500 therein, to the test slot 310 for testing of the storage device 500. After testing, the robotic arm 200 retrieves the tested storage device 500 from the test slot 310, by removing the storage device transporter 550 carrying the tested storage device 500 from the test slot 310 (i.e., with the manipulator 212), carrying the tested storage device 500 in the storage device transporter 550 to the transfer station 400, and manipulating the storage device transporter 550 to return the tested storage device 500 to one of the storage device receptacles 454 at the transfer station 400. In implementations that include a vision system 270 on the robotic arm 200, the fiducial mark 314 may be located adjacent one or more storage device receptacles 454 to aid guidance of the robotic arm in retrieving or depositing storage devices 500 at the transfer station 400.

The transfer station 400, in some examples, includes a station housing 410 that defines a longitudinal axis 415. One or more tote receivers 420 are rotatably mounted in the station housing 410, for example on a spindle 412 extending along the longitudinal axis 415. Each tote receiver 420 may rotate on an individual respective spindle 412 or on a common spindle 412. Each tote receiver 420 defines first and second opposite facing tote receptacles 430A and 430B. In the example shown, the transfer station 400 includes three tote receivers 420 stacked on the spindle 412. Each tote receiver 420 is independently rotatable from the other and may rotate a received storage device tote 450 between a servicing position (e.g. accessible by an operator) and a testing position accessible by the robotic arm 200. In the example shown, each tote receiver 420 is rotatable between a first position (e.g. servicing position) and a second position (testing position). While in the first position, an operator is provided access to the first tote receptacle 430A, and the robotic arm 200 is provided access on the opposite side to the second tote receptacle 430B. While in the second position the robotic arm 200 is provided access the first tote receptacle 430A, and an operator is provided access on the opposite side to the second tote receptacles 430B. As a result, an operator may service the transfer station 400 by loading/unloading totes 450 into tote receptacles 430 on one side of the transfer station 400, while the robotic arm 200 has access to totes 450 housed in tote receptacles 430 on an opposite side of the transfer station 400 for loading/unloading storage devices 500.

The transfer station 400 provides a service point for delivering and retrieving storage devices 500 to and from the storage device testing system 100. The totes 450 allow an operator to deliver and retrieve a batch of storage devices 500 to and from the transfer station 400. In the example shown in FIG. 10, each tote 450 that is accessible from respective tote receivers 420 in the second position may be designated as source totes 450 for supplying storage devices 500 for testing or as destination totes 450 for receiving tested storage devices 500. Destination totes 450 may be classified as “passed return totes” or “failed return totes” for receiving respective storage devices 500 that have either passed or failed a functionality test, respectively.

A housing door 416 is pivotally or slidably attached to the transfer station housing 410 and configured to provide operator access to one or more tote receptacles 430. An operator opens the housing door 416 associated with a particular tote receiver 420 to load/unload a tote 450 into the respective tote receptacle 430. The transfer station 400 may be configured to hold the respective tote receiver 420 stationary while the associated housing door 416 is open.

In some examples, the transfer station 400 includes a station indicator 418 which provides visual, audible, or other recognizable indications of one or more states of the transfer station 400. In one example, the station indicator 418 includes lights (e.g. LED's) that indicate when one or more tote receivers 420 need servicing (e.g. to load/unload totes 450 from particular tote receives 420). In another example, the station indicator 418 includes one or more audio devices to provide one or more audible signals (e.g. chirps, clacks, etc.) to signal an operator to service the transfer station 400. The station indicator 418 may be disposed along the longitudinal axis 415, as shown, or on some other portion of the station housing 410.

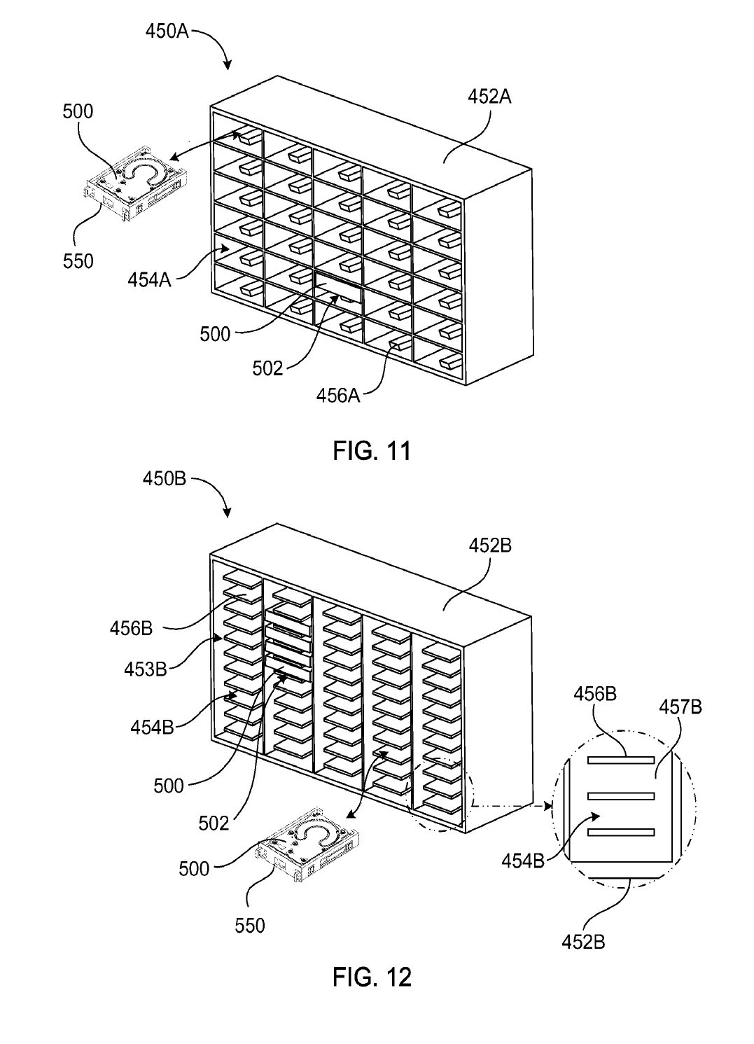

In the example illustrated in FIG. 11, a tote 450A includes a tote body 452A that defines multiple storage device receptacles 454A. Each storage device receptacle 454A is configured to house a storage device 500. In this example, each storage device receptacle 454A includes a storage device support 456A configured to support a central portion 502 of the received storage device 500 to allow manipulation of the storage device 500 along non-central portions. To remove a housed storage device 500 from the storage device receptacle 454A, the storage device transporter 550 is positioned below the storage device 500 (e.g. by the robotic arm 200) in the storage device receptacle 454A and elevated to lift the storage device 500 off of the storage device support 456A. The storage device transporter 550 is then removed from the storage device receptacle 454A while carrying the storage device 500 for delivery to a destination target, such as a test slot 310.

In the example illustrated in FIG. 12, a tote 450B includes a tote body 452B that defines column cavities 453B divided into storage device receptacles 454B by multiple storage device supports 456B. The storage device supports 456B are cantilevered off a rear wall 457B of the column cavity 453B. The storage device supports 456B are configured to support a central portion 502 of the received storage device 500 to allow manipulation of the storage device 500 along non-central portions. The cantilevered storage device supports 456B allow retrieval of storage devices 500 from the tote 450B by inserting a storage device transporter 550 (e.g. as shown in FIG. 13) into an empty storage device receptacle 454B just below and lifting the storage device 500 off the storage device support 456B for removal from the storage device receptacle 454B. The same steps are repeated in reverse for depositing the storage device 500 in the tote 450B. As shown, the bottom storage device receptacle 454B in each column cavity 453B is left empty to facilitate removal of a storage device 500 housed in the storage device receptacle 454B above it. Consequently, the storage devices 500 must be loaded/unloaded in a sequential order in a particular column; however a greater storage density is achieved than the tote solution shown in FIG. 11.

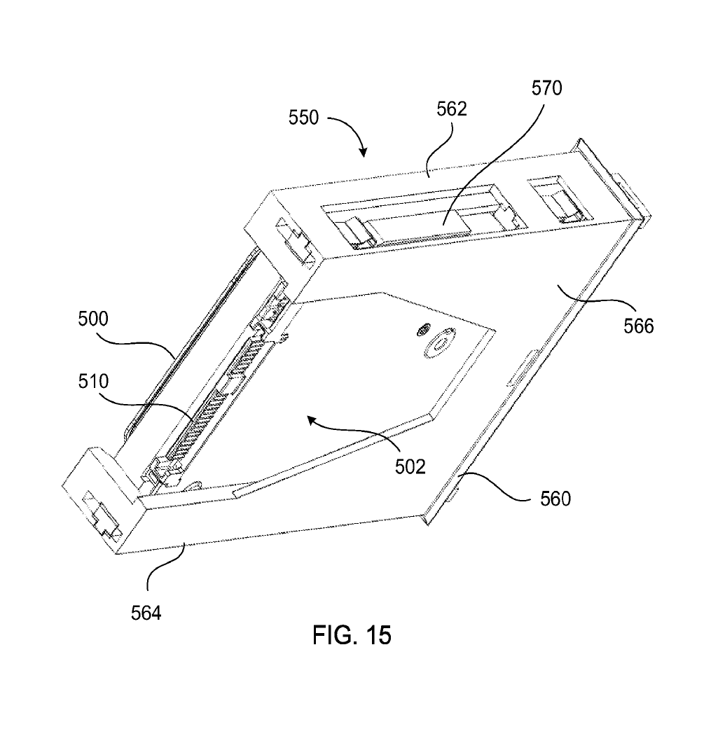

Referring to FIGS. 13-16, in some examples, the test slot 310 is configured to receive the storage device transporter 550. The storage device transporter 550 is configured to receive the storage device 500 and be handled by the robotic arm 200. In use, one of the storage device transporters 550 is removed from one of the test slots 310 with the robot 200 (e.g., by grabbing, or otherwise engaging, the indentation 552 of the transporter 550 with the manipulator 212 of the robot 200). As illustrated in FIG. 13, the storage device transporter 550 includes a frame 560 defining a substantially U-shaped opening 561 formed by sidewalls 562, 564 and a base plate 566 that collectively allow the frame 560 to fit around the storage device support 456 in the tote 450 so that the storage device transporter 550 can be moved (e.g., via the robotic arm 200) into a position beneath one of the storage devices 500 housed in one of the storage device receptacles 454 of the tote 450. The storage device transporter 550 can then be raised (e.g., by the robotic arm 310) into a position engaging the storage device 600 for removal off of the storage device support 456 in the tote 450.

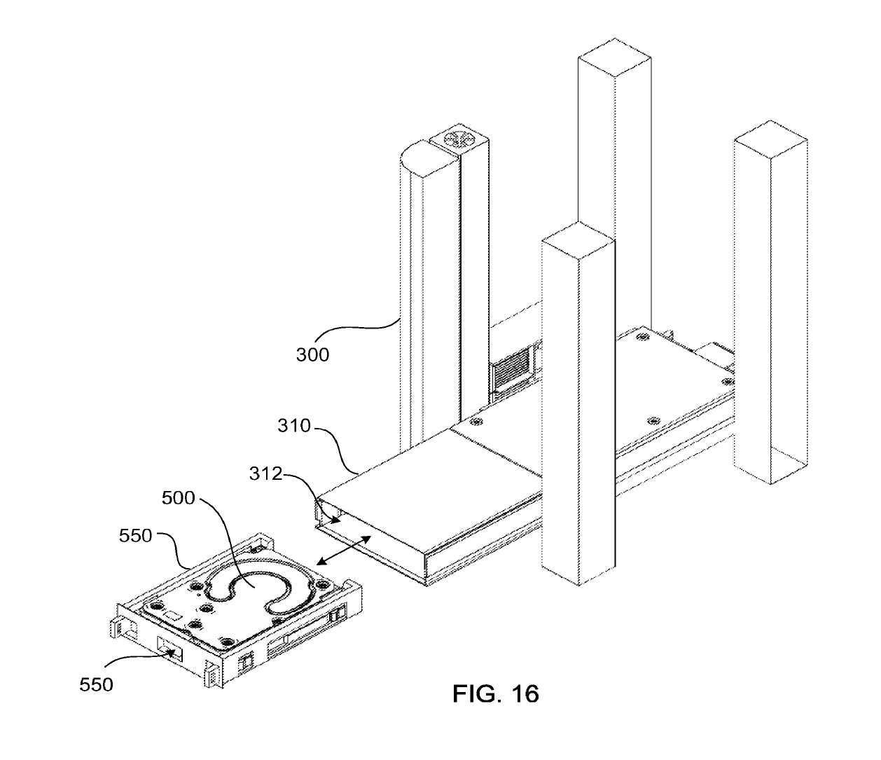

With the storage device 500 in place within the frame 560 of the storage device transporter 550, the storage device transporter 550 and the storage device 500 together can be moved by the robotic arm 200 for placement within one of the test slots 310, as shown in FIG. 16. The manipulator 212 is also configured to initiate actuation of a clamping mechanism 570 disposed in the storage device transporter 550. This allows actuation of the clamping mechanism 570 before the transporter 550 is moved from the tote 450 to the test slot 310 to inhibit movement of the storage device 500 relative to the storage device transporter 550 during the move. Prior to insertion in the test slot 310, the manipulator 212 can again actuate the clamping mechanism 570 to release the storage device 500 within the frame 560. This allows for insertion of the storage device transporter 550 into one of the test slots 310, until the storage device 500 is in a test position with a storage device connector 510 engaged with a test slot connector (not shown). The clamping mechanism 570 may also be configured to engage the test slot 310, once received therein, to inhibit movement of the storage device transporter 550 relative to the test slot 310. In such implementations, once the storage device 500 is in the test position, the clamping mechanism 570 is engaged again (e.g., by the manipulator 212) to inhibit movement of the storage device transporter 550 relative to the test slot 310. The clamping of the storage device transporter 550 in this manner can help to reduce vibrations during testing. In some examples, after insertion, the storage device transporter 550 and storage device 500 carried therein are both clamped or secured in combination or individually within the test slot 310. A detailed description of the clamping mechanism 570 and other details and features combinable with those described herein may be found in U.S. patent application Ser. No. 11/959,133, filed Dec. 18, 2007, entitled “DISK DRIVE TRANSPORT, CLAMPING AND TESTING”, the contents of which are hereby incorporated by reference in its entirety.

The storage devices 500 can be sensitive to vibrations. Fitting multiple storage devices 500 in a single test rack 310 and running the storage devices 500 (e.g., during testing), as well as the insertion and removal of the storage device transporters 550, each optionally carrying a storage device 500, from the various test slots 310 in the test rack 300 can be sources of undesirable vibration. In some cases, for example, one of the storage devices 500 may be operating under test within one of the test slots 310, while others are being removed and inserted into adjacent test slots 310 in the same test rack 300. Clamping the storage device transporter 550 to the test slot 310 after the storage device transporter 550 is fully inserted into the test slot 310, as described above, can help to reduce or limit vibrations by limiting the contact and scraping between the storage device transporters 550 and the test slots 310 during insertion and removal of the storage device transporters 550.

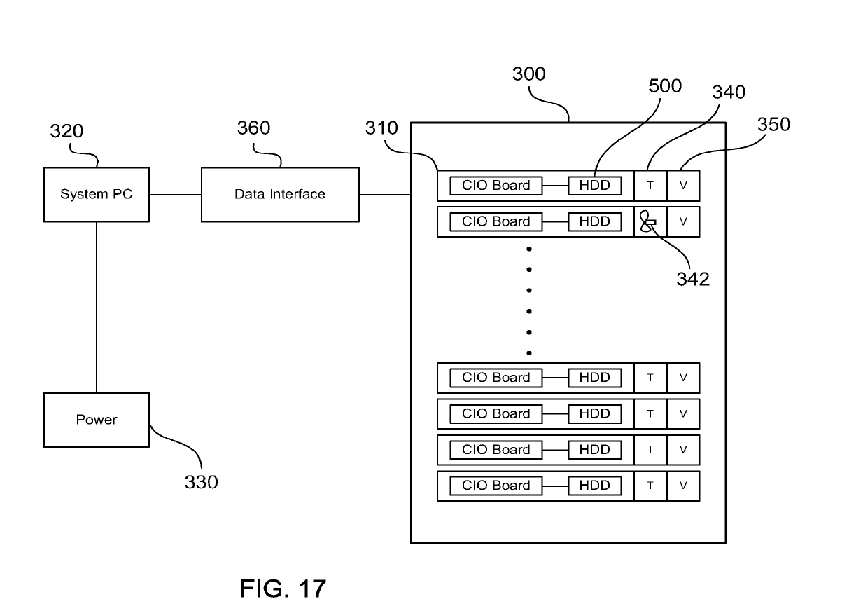

Referring to FIG. 17, in some implementations, the storage device testing system 100 includes at least one computer 320 in communication with the test slots 310. The computer 320 may be configured to provide inventory control of the storage devices 500 and/or an automation interface to control the storage device testing system 100. A power system 330 supplies power to the storage device testing system 100. The power system 330 may monitor and/or regulate power to the received storage device 500 in the test slot 310. A temperature control system 340 controls the temperature of each test slot 310. The temperature control system 340 may be an air mover 342 (e.g. a fan) operable to circulate air over and/or through the test slot 310. In some examples, the air mover 342 is located exteriorly of the test slot 310. A vibration control system 350, such as active or passive dampening, controls the vibration of each test slot 310. In some examples, the vibration control system 350 includes a passive dampening system where components of the test slot 310 are connected via grommet isolators (e.g. thermoplastic vinyl) and/or elastomeric mounts (e.g. urethane elastomer). In some examples, the vibration control system 350 includes an active control system with a spring, damper, and control loop that controls the vibrations in the rack 300 and/or test slot 310. A data interface 360 is in communication with each test slot 310. The data interface 360 is configured to communicate with a storage device 500 received by the test slot 310.

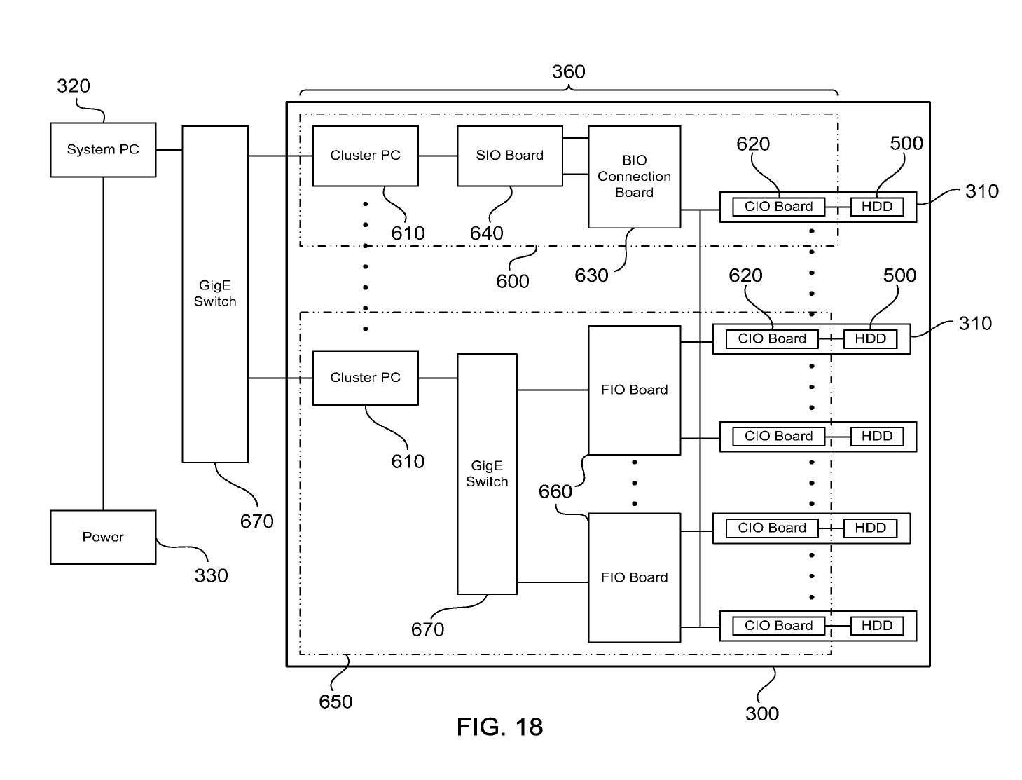

In the example illustrated in FIG. 18, each rack 300 includes at least one self-testing system 600 in communication with at least one test slot 310. The self-testing system 600 includes a cluster controller 610, a connection interface circuit 620 in electrical communication with a storage device 500 received in the test slot 310, and a block interface circuit 630 in electrical communication with the connection interface circuit 620. The cluster controller 610 may be configured to run one or more testing programs, such as multiple self-tests on test slots 310 and/or functionality tests on storage devices 500. The connection interface circuit 620 and the block interface circuit 630 may be configured to self-test. However, in some examples, the self-testing system 600 includes a self-test circuit 660 configured to execute and control a self-testing routine on one or more components of the storage device testing system 100. For example, the self-test circuit 660 may be configured to perform a ‘storage device’ type and/or ‘test slot only’ type of self-test on one or more components of the storage device testing system 100. The cluster controller 610 may communicate with the self-test circuit 640 via Ethernet (e.g. Gigabit Ethernet), which may communicate with the block interface circuit 630 and onto the connection interface circuit 620 and storage device 500 via universal asynchronous receiver/transmitter (UART) serial links. A UART is usually an individual (or part of an) integrated circuit used for serial communications over a computer or peripheral device serial port. The block interface circuit 630 is configured to control power and temperature of the test slot 310, and may control multiple test slots 310 and/or storage devices 500.

Each rack 300, in some examples, includes at least one functional testing system 650 in communication with at least one test slot 310. The functional testing system 650 tests whether a received storage device 500, held and/or supported in the test slot 310 by the storage device transporter 550, is functioning properly. A functionality test may include testing the amount of power received by the storage device 500, the operating temperature, the ability to read and write data, and the ability to read and write data at different temperatures (e.g. read while hot and write while cold, or vice versa). The functionality test may test every memory sector of the storage device 500 or only random samplings. The functionality test may test an operating temperature of the storage device 500 and also the data integrity of communications with the storage device 500. The functional testing system 650 includes a cluster controller 610 and at least one functional interface circuit 660 in electrical communication with the cluster controller 610. A connection interface circuit 620 is in electrical communication with a storage device 500 received in the test slot 310 and the functional interface circuit 660. The functional interface circuit 660 is configured to communicate a functional test routine to the storage device 500. The functional testing system 650 may include a communication switch 670 (e.g. Gigabit Ethernet) to provide electrical communication between the cluster controller 610 and the one or more functional interface circuits 660. Preferably, the computer 320, communication switch 670, cluster controller 610, and functional interface circuit 660 communicate on an Ethernet network. However, other forms of communication may be used. The functional interface circuit 660 may communicate to the connection interface circuit 620 via Parallel AT Attachment (a hard disk interface also known as IDE, ATA, ATAPI, UDMA and PATA), SATA, or SAS (Serial Attached SCSI).

A method of performing storage device testing includes loading multiple storage devices 500 into a transfer station 400 (e.g. as by loading the storage devices 500 into storage device receptacles 454 defined by a storage device tote 450, and loading the storage device tote 450 into a tote receptacle 430 defined by the transfer station 400). The method includes actuating a robotic arm 200 to retrieve a storage device transporter 550 from a test slot 310 housed in a rack 300, and actuating the robotic arm 200 to retrieve one of the storage devices 500 from the transfer station 400 and carry the storage device 500 in the storage device transporter 550. The robotic arm 200 is operable to rotate through a predetermined arc about, and to extend radially from, a first axis 205 defined by the robotic arm 200 substantially normal to a floor surface 10. The method includes actuating the robotic arm 200 to deliver the storage device transporter 550 carrying the storage device 500 to the test slot 310, and performing a functionality test on the storage device 500 housed by the received storage device transporter 550 and the test slot 310. The method then includes actuating the robotic arm 200 to retrieve the storage device transporter 550 carrying the tested storage device 500 from the test slot 310 and deliver the tested storage device 500 back to the transfer station 400. In some implementations, the rack 300 and two or more associated test slots 310 are configured to move storage devices 500 internally from one test slot 310 to another test slot 310, in case the test slots 310 are provisioned for different kinds of tests.

In some examples, the method includes actuating the robotic arm 200 to deposit the storage device transporter 550 in the test slot 310 after depositing the tested storage device 500 in a storage device receptacle 454 of the storage device tote 450, or repeating the method by retrieving another storage device 500 for testing from another storage device receptacle 454 of the storage device tote 450. In some examples, delivering the storage device transporter 550 to the test slot 310 includes inserting the storage device transporter 550 carrying the storage device 500 into the test slot 310 in the rack 300, establishing an electric connection between the storage device 500 and the rack 300.

In some implementations, the method includes performing a functionality test on the received storage device 500 that includes regulating the temperature of the test slot 310 while operating the storage device 500. Operation of the received storage device 500 includes performing reading and writing of data to the storage device 500. The method may also include circulating air over and/or through the test slot 310 to control the temperature of the test slot 310, and monitoring and/or regulating power delivered to the storage device 500.

In some examples, the method includes performing a ‘storage device’ type and/or ‘test slot only’ type of self-test on the test slot 320 with the self-testing system 600 housed by the rack 300 to verify the functionality of the test slot 310. The ‘storage device’ type self-test tests the functionality of the storage device testing system with a received storage device 500, held and/or supported in the test slot 310 by the storage device transporter 550. The ‘test slot only’ type of self-test tests the functionality of the test slot 310 while empty.

In some examples, the method includes communicating with the vision system 270 disposed on the robotic arm 200 to aid guidance of the robotic arm 200 while transporting the storage device 500, which may be carried by a storage device transporter 550. The method includes calibrating the robotic arm 200 by aligning the robotic arm 200 to a fiducial mark 314 on the rack 300, test slot 310, transfer station 400 and/or tote 450 recognized by the vision system 270.

Other details and features combinable with those described herein may be found in U.S. patent application Ser. No. 11/958,817, filed Dec. 18, 2007, entitled “DISK DRIVE TESTING”, the contents of which are hereby incorporated by reference in its entirety.

A number of implementations have been described. Nevertheless, it will be understood that various modifications may be made without departing from the spirit and scope of the disclosure. Accordingly, other implementations are within the scope of the following claims.

1. A storage device testing system comprising:
at least one robotic arm defining a first axis substantially normal to a floor surface, the robotic arm operable to rotate through a predetermined arc about, and extend radially from, the first axis
multiple racks arranged around the robotic arm for servicing by the robotic arm; and
multiple test slots housed by each rack, each test slot being configured to receive a storage device transporter configured to carry a storage device for testing.

2. The storage device testing system of claim 1, wherein the robotic arm comprises a manipulator configured to engage the storage device transporter of one of the test slots, the robotic arm being operable to carrying a storage device in the storage device transporter to the test slot for testing.

3. The storage device testing system of claim 1, wherein the racks are arranged equidistantly radially away from and/or in at least a partially closed polygon about the first axis of the robotic arm.

4. The storage device testing system of claim 1, further comprising:
at least one computer in communication with the test slots;
a power system for supplying power to the storage device testing system;
a temperature control system for controlling the temperature of each test slot;
a vibration control system for controlling rack vibrations; and
a data interface in communication with each test slot, the data interface configured to communicate with a storage device in the storage device transporter received by the test slot.

5. (canceled)

6. The storage device testing system of claim 4, wherein the temperature control system (340) comprises an air mover (342) operable to circulate air through the test slot (310).

7. (canceled)

8. The storage device testing system of claim 1, wherein each rack comprises at least one functional testing system in communication with at least one test slot, the functional testing system comprising:
a cluster controller;
at least one functional interface circuit in electrical communication with the cluster controller; and
a connection interface circuit in electrical communication with a storage device received in the test slot and the at least one functional interface circuit, wherein the at least one functional interface circuit is configured to communicate a functional test routine to the storage device.

9. The storage device testing system of claim 8, wherein the functional testing system further comprises a communication switch, preferably and Ethernet switch, for providing electrical communication between the cluster controller and the at least one functional interface circuit.

10. The storage device testing system of claim 1, wherein the robotic arm defines a substantially cylindrical working envelope volume, the racks being arranged within the working envelope volume for accessibility of each test slot for servicing by the robotic arm.

11. The storage device testing system of claim 1, wherein the robotic arm independently services each test slot by retrieving the storage device transporter from one of the test slots to transfer a storage device between a transfer station and the test slot.

12-14. (canceled)

15. The storage device testing system of claim 1, further comprising a rotatable table supporting the robotic arm and being operable to rotate the robotic arm about a second axis substantially normal to the floor surface.

16. The storage device testing system of claim 1, further comprising a vision system disposed on the robotic arm, the vision system aiding guidance of the robotic arm while transporting a storage device and calibration of the robotic arm by aligning the robotic arm to a fiducial mark.

17. The storage device testing system of claim 1, further comprising a transfer station arranged for servicing by the robotic arm, the transfer station supplying storage devices for testing.

18. A method of performing storage device testing comprising:
presenting a storage device for testing;
actuating a single robotic arm to retrieve the presented storage device and carry the storage device to a test slot housed in a rack of a storage device testing system, the robotic arm operable to rotate through a predetermined arc about and to extend radially from a first axis defined by the robotic arm substantially normal to a floor surface;
actuating the robotic arm to insert the storage device into the test slot;
performing a functionality test on the storage device housed in the test slot; and
actuating the robotic arm to retrieve the tested storage device from the test slot and deliver the tested storage device to a tested complete location.

19. The method of claim 18, further comprising:
loading the storage device into a transfer station, the storage device being presented for testing;
actuating the robotic arm to retrieve a storage device transporter from the test slot;
actuating the robotic arm to retrieve the presented storage device from the transfer station and carry the storage device in the storage device transporter;
actuating the robotic arm to deliver the storage device transporter carrying storage device to the test slot; and
actuating the robotic arm to retrieve the storage device transporter carrying the tested storage device from the test slot and deliver the tested storage device back to the transfer station.

20. The method of claim 18, further comprising actuating the robotic arm to deposit the empty storage device transporter in the test slots.

21. The method of any of claim 18, wherein performing a functionality test on the received storage device comprises regulating the temperature of the test slot while operating the storage device, in particular, performing reading and writing of data to the storage device.

22. The method of any of claim 18, further comprising circulating air through the test slot to control the temperature of the test slot.

23. (canceled)

24. The method of claim 18, further comprising regulating power delivered to the storage device received in the test slot.

25. The method of claim 18, further comprising performing a self-test on the test slot with a self-testing system housed by the rack to verify the functionality of the test slot.

26-27. (canceled)

28. The method claim 18, further comprising communicating with a vision system disposed on the robotic arm to aid guidance of the robotic arm while transporting the storage device and/or for calibrating the robotic arm by aligning the robotic arm to a fiducial mark on the rack.
